(19) United States
(12) Patent Application Publication
(10) Pub. No.: US 2026/0136596 A1
(43) Pub. Date: May 14, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chun Yi Chou, Hsinchu City (TW); Kuo-Cheng CHIANG, Hsinchu County (TW); Chih-Hao Wang, Hsinchu County (TW)

(73) Assignee: Taiwan Semiconductor Manufacturing Company, Ltd., Hsinchu (TW)

(21) Appl. No.: 18/946,993

(22) Filed: Nov. 14, 2024

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/018

(57) ABSTRACT

A semiconductor device includes a semiconductor substrate, semiconductor channel layers disposed over the semiconductor substrate and vertically spaced apart from one another, a gate structure disposed between adjacent two of the semiconductor channel layers and between the semiconductor substrate and a bottommost one of the semiconductor channel layers, source/drain (S/D) structures disposed over the semiconductor substrate and laterally connecting the semiconductor channel layers, and a liner layer including a first portion disposed below the S/D structures to isolate each of the S/D structures from the semiconductor substrate. The gate structure is disposed between the S/D structures, and hollow regions below the S/D structures are encircled by the first portion of the liner layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. However, such scaling has also introduced increased complexity to the semiconductor manufacturing process. Thus, the realization of continued advances in ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-20 illustrate schematic various views of intermediate steps during a process for forming a semiconductor device, in accordance with some embodiments.

FIGS. 21-22 illustrate schematic cross-sectional views of intermediate steps during a process for forming a semiconductor device, in accordance with some embodiments.

FIGS. 23-25 illustrates schematic cross-sectional views of variations of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the disclosure describe a manufacturing process of a semiconductor device (or a portion of a nanostructure transistor device). The nanostructure transistor device (also referred to as a gate-all-around (GAA) transistor device) may include a gate structure wrapping around the perimeter of one or more nanostructures (i.e. channel regions) for improved control of channel current flow. The embodiments are not limited in this context. The semiconductor device may be included in microprocessors, memories, and/or other integrated circuits (IC). Accordingly, it is understood that additional processes may be provided before, during, and after the illustrated method, and that some other processes may only be briefly described herein. Also, the structures illustrated in the drawings are simplified for a better understanding of the concepts of the present disclosure. For example, although the figures illustrate the structure of the semiconductor device, it is understood the semiconductor device may be part of an IC that further includes a number of other devices such as resistors, capacitors, inductors, fuses, etc.

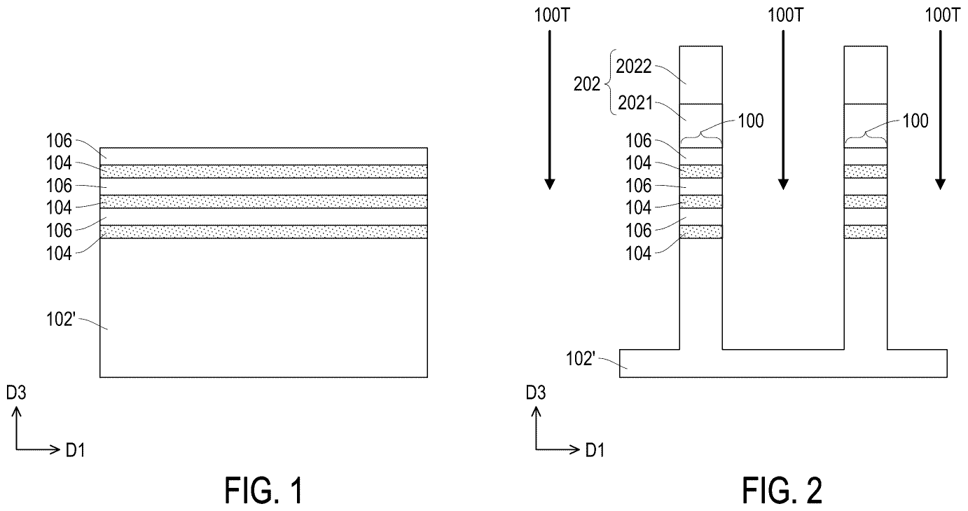

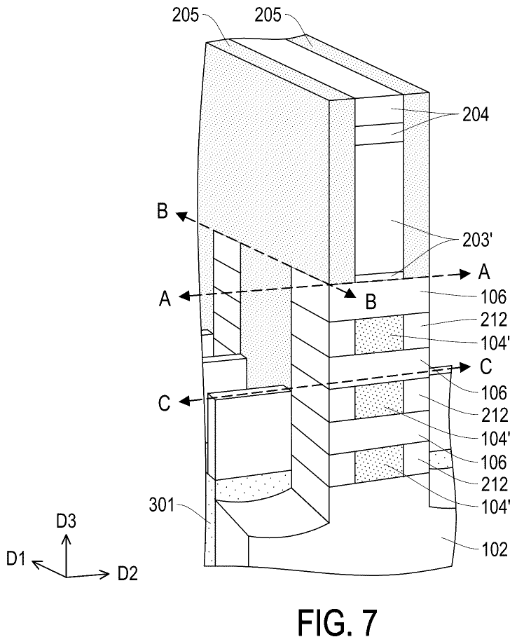

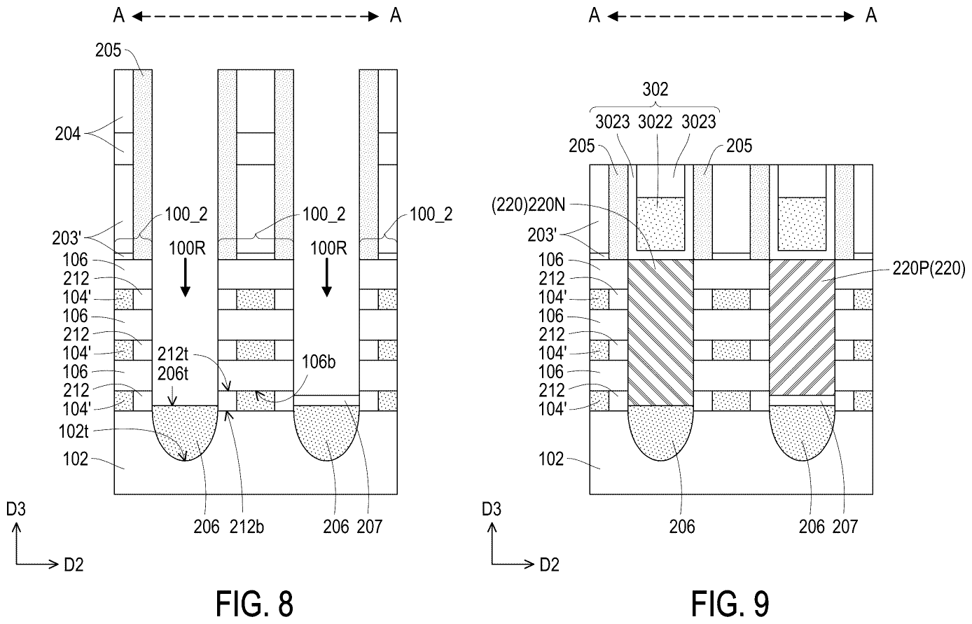

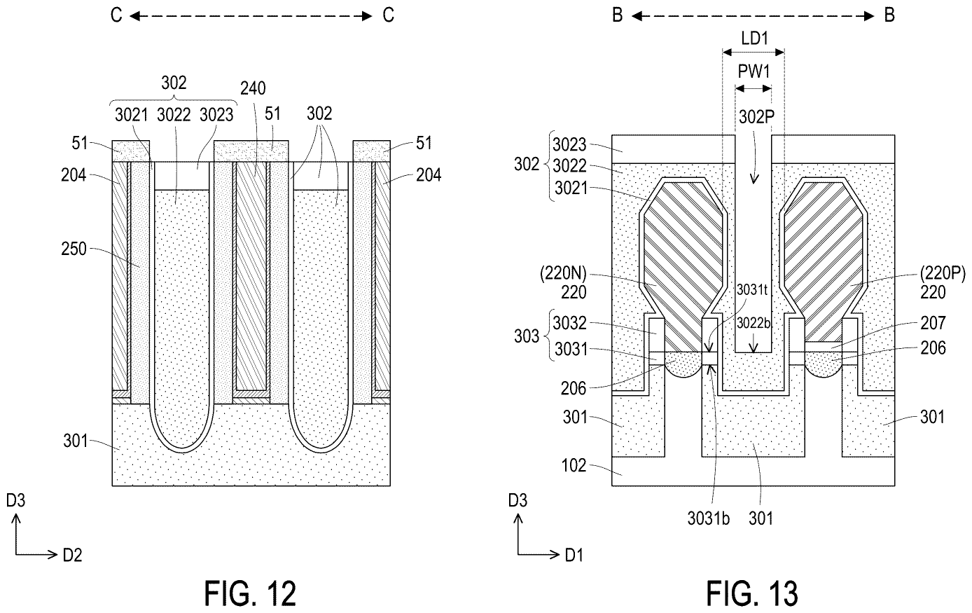

FIGS. 1-20 illustrate schematic various views of intermediate steps during a process for forming a semiconductor device, in accordance with some embodiments. For clarity of illustrations, in the drawings are illustrated the directions (e.g., D1, D2 and D3) of the coordinate system according to which the views are oriented, where the directions D1, D2 and D3 are substantially perpendicular to one another. It should be noted that FIG. 7 is a schematic perspective view of the structure illustrated in FIG. 6, FIGS. 8-10, 17, and 19 are schematic cross-sectional views taken along the line A-A in FIG. 7, FIGS. 11, 13-16, 18, and 20 are schematic cross-sectional views taken along the line B-B in FIG. 7, and FIG. 12 is a schematic cross-sectional view taken along the line C-C in FIG. 7, in accordance with some embodiments.

Referring to FIG. 1, a stack of first semiconductor layers 104 and second semiconductor layers 106 may be formed on a semiconductor substrate 102′. In some embodiments, the semiconductor substrate 102′ includes a crystalline silicon substrate or a bulk silicon substrate (e.g., wafer). In some embodiments, the semiconductor substrate 102′ is made of a suitable elemental semiconductor (e.g., germanium), a suitable compound semiconductor (e.g., gallium arsenide, silicon carbide, indium arsenide, or indium phosphide), a suitable alloy semiconductor (e.g., silicon germanium carbide, gallium arsenic phosphide, or gallium indium phosphide), and/or the like. In some embodiments, the semiconductor substrate 102′ includes a semiconductor-on-insulator (SOI) substrate. The semiconductor substrate 102′ may include various doped regions (not individually shown) doped with p-type or n-type dopants, where the doped regions may be configured for an n-type field effect transistor (FET), or alternatively, configured for a p-type FET.

With continued reference to FIG. 1, the first semiconductor layers 104 and the second semiconductor layers 106 may be alternately stacked upon one another (e.g., along the direction D3) to form a stack. The first semiconductor layers 104 may be considered sacrificial layers in the sense that they are removed in the subsequent process (see FIG. 13). In some embodiments, the bottommost one of the first semiconductor layers 104 is formed on the semiconductor substrate 102′, with the remaining second and first semiconductor layers (106 and 104) alternately stacked on top. However, either the first semiconductor layer 104 or the second semiconductor layer 106 may be the bottommost layer (or the layer most proximate from the semiconductor substrate 102′), and either the first semiconductor layer 104 or the second semiconductor layer 106 may be the topmost layer (or the layer most distanced to the semiconductor substrate 102′). The disclosure is not limited by the number of stacked semiconductor layers (e.g., 104 and 106).

With continued reference to FIG. 1, the first semiconductor layers 104 and the second semiconductor layers 106 may have different materials (or compositions) that may provide for different oxidation rates and/or different etch selectivity between the layers. For example, the second semiconductor layers 106 are formed of the same material as the semiconductor substrate 102′, while the first semiconductor layers 104 may be formed of a different material which may be selectively removed with respect to the material of the semiconductor substrate 102′ and the second semiconductor layers 106. In some embodiments, the material of the first semiconductor layers 104 includes silicon germanium. In some embodiments, the second semiconductor layers 106 include silicon, where each of the second semiconductor layers 106 may be undoped or substantially dopant-free. However, the disclosure is not limited thereto, and other suitable material, or other combinations of materials for which selective etching is possible are contemplated within the scope of the disclosure. The second semiconductor layers 106 may be semiconductor nanosheets and may be considered as channel regions in the subsequent processes. The terms “semiconductor nanosheets” and “channel regions” may be used interchangeably herein.

Referring to FIG. 2 and with reference to FIG. 1, a portion of the stack of first semiconductor layers 104 and second semiconductor layers 106 and the underlying portion of the semiconductor substrate 102′ may be removed to form trenches 100T, thereby defining a fin structure 100 between adjacent trenches 100T. Each trench 100T may be disposed between adjacent two of the fin structures 100. The lengthwise direction (e.g., the direction D2 labeled in FIG. 7) of the fin structure 100 may be referred to as the X-cut direction. In some embodiments, the fin structure 100 is formed by patterning the stack of first semiconductor layers 104 and second semiconductor layers 106 and the underlying semiconductor substrate 102′ by using, e.g., lithography and etching, or other suitable techniques.

In some embodiments, a mask layer 202 is first formed over the top the stack, e.g., on the topmost one of the second semiconductor layers 106. The mask layer 202 may be a single layer or include more than one sublayer (e.g., a first mask sublayer 2021 overlying the topmost second semiconductor layer 106 and a second mask sublayer 2022 overlying the first mask sublayer 2021). In some embodiments, each of the sublayers (e.g., 2021 and 2022) is formed of a semiconductor material similar to the material of first and second semiconductor layer (e.g., 104 or 106) or is formed of different dielectric materials. The mask layer 202 may be used to pattern exposed portions of the stack of first semiconductor layers 104 and second semiconductor layers 106 and the underlying semiconductor substrate 102′. For example, the fin structure 100 is formed by etching the trenches 100T at exposed portions of the stack of first semiconductor layers 104 and second semiconductor layers 106 and the semiconductor substrate 102′ which are not covered by the mask layer 202.

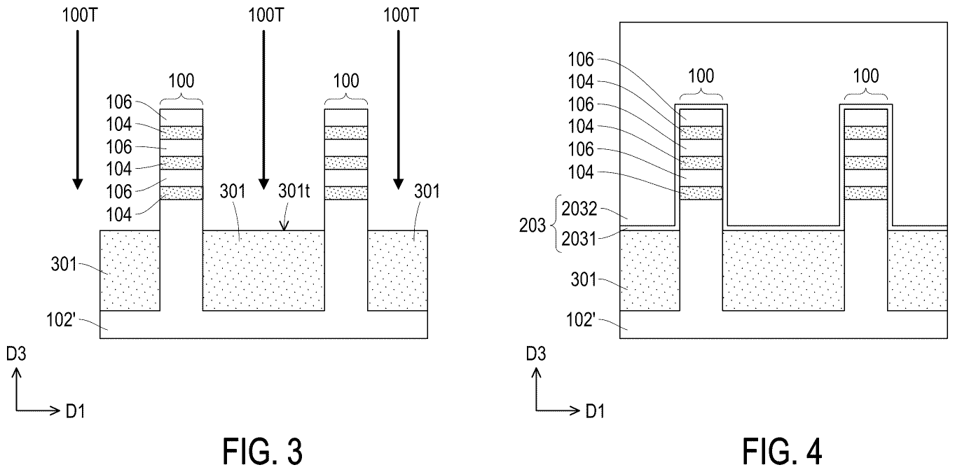

Referring to FIG. 3 and with reference to FIG. 2, a plurality of isolation structures 301 (also referred to as shallow trench isolation (STI) structures) may be formed in lower portions of the trenches 100T. For example, the isolation structures 301 extend at opposing sides of a lower portion of the semiconductor substrate 102′. In some embodiments, each of the isolation structures 301 is disposed between adjacent two of the fin structures 100 and covers a sidewall of a lower portion of the respective fin structure 100. The isolation structures 301 may each be formed of one or more insulation material(s) (e.g., an oxide, a Si-based oxide (e.g., SiOC, SiOCN, or the like), a nitride, the like, any other suitable material(s), combinations thereof, etc.) which may electrically isolate neighboring fin structures 100 from each other. In some embodiments, a hard mask structure (not shown in this view, but illustrated in FIG. 11 and labeled as “303”) including one or more dielectric material(s) is formed on the respective isolation structure 301 for protection. The hard mask structure overlying the isolation structures 301 may be referred to as the STI hard mask structure.

With continued reference to FIG. 3 and FIG. 2, the isolation structures 301 may be formed by initially depositing a layer of insulation material(s) in the respective trench 100T and recessing the layer of insulation material(s) using a chemical mechanical polishing (CMP) process followed by an acceptable etching process, such as one that is selective to the material(s) of the isolation structures 301. During the recessing, the first mask sublayer 2021 and the second mask sublayer 2022 left on the fin structures 100 may serve as the etch masks. The isolation structures 301 may be recessed, and thus the fin structure 100 is protruded from the neighboring isolation structures 301. The top surfaces 301t of the isolation structures 301 may be a flat surface, a curved (e.g., convex or concave) surface, or combinations thereof, depending on the etching process. After (or during) the formation of the isolation structures 301, the first mask sublayer 2021 and the second mask sublayer 2022 may be removed from the fin structures 100, and the topmost second semiconductor layer 106 of the stack may then be accessibly exposed.

Referring to FIG. 4 and with reference to FIG. 3, a dummy gate structure 203 may be formed on the fin structures 100. The dummy gate structure 203 may also be formed in the trenches 100T and on the isolation structures 301. The dummy gate structure 203 may have the lengthwise direction along the direction D1 which is substantially perpendicular to the lengthwise direction of the respective fin structure 100. For example, the dummy gate structure 203 includes a dummy dielectric layer 2031 covering the fin structures 100 and the isolation structures 301 and a dummy gate layer 2032 formed on the dummy dielectric layer 2031. In some embodiments, the dummy dielectric layer 2031 covers the top surfaces 301t of the isolation structures 301 and may extend between the dummy gate layer 2032 and the isolation structures 301. The dummy dielectric layer 2031 may be or include silicon oxide, silicon nitride, a combination thereof, or the like, and may be deposited according to acceptable techniques. The dummy gate layer 2032 may be a conductive or non-conductive material and may be selected from a group including amorphous silicon, polysilicon, poly-crystalline silicon-germanium, metallic oxides, and metals, and may be formed by using physical vapor deposition (PVD), chemical vapor deposition (CVD), atomic layer deposition (ALD), sputtering, or other suitable techniques.

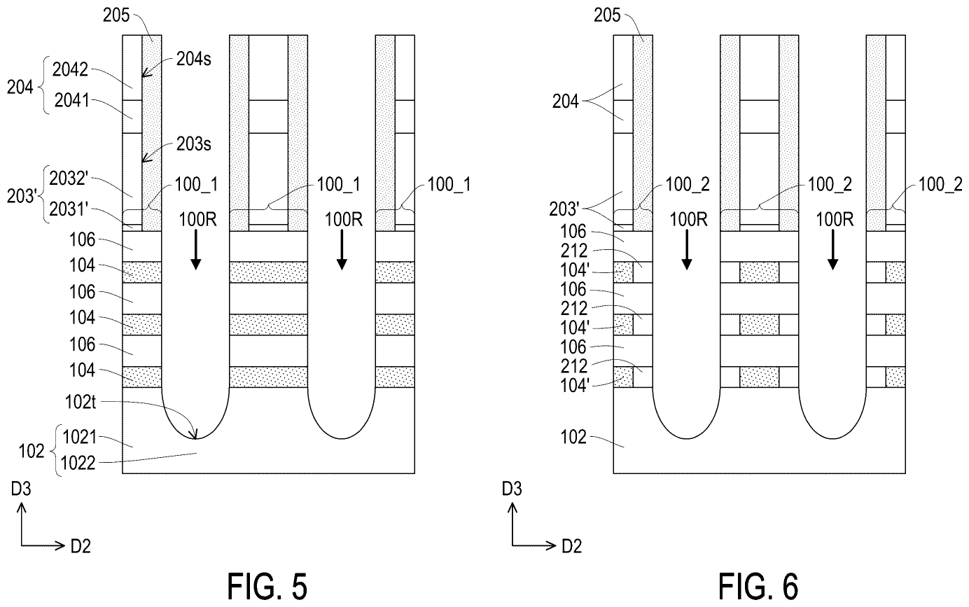

Referring to FIG. 5 and with reference to FIG. 4, a mask layer 204 may be formed on the dummy gate structure 203. The mask layer 204 may be a single mask layer or include multiple sublayers formed of different materials including silicon nitride, silicon oxynitride, or the like. In the illustrated embodiment, the mask layer 204 includes a first mask sublayer 2041 overlying the dummy gate structure 203 and a second mask sublayer 2042 overlying the first mask sublayer 2041. For example, one or more mask material(s) may be initially formed and then patterned using acceptable lithography and etching techniques to form the mask layer 204. Next, the pattern of the mask layer 204 may be transferred to the dummy gate structure 203 to form the patterned dummy gate structure 203′ including the patterned dummy gate layer 2032′ and the patterned dummy dielectric layer 2031′.

With continued reference to FIG. 5 and FIG. 4, a sidewall spacer layer 205 may then be formed on sidewalls of the mask layer 204 and the patterned dummy gate structure 203′. The sidewall spacer layer 205 may be a single layer or may include multiple sublayers formed of different materials including silicon oxide, silicon nitride, silicon oxynitride, or the like. The sidewall spacer layer 205 may be deposited by thermal oxidation or deposited by CVD, ALD, PVD, or the like. The sidewall spacer layer 205 may act to self-align subsequently formed source/drain (S/D) regions, as well as to protect sidewalls of the respective fin structure 100 during subsequent processing. In some embodiments, the sidewall spacer layer 205 is disposed on the sidewalls 203s of the patterned dummy gate structure 203′ and extends to cover sidewalls 204s of the mask layer 204.

With continued reference to FIG. 5 and FIG. 4, a portion of the respective fin structure 100 and a portion of the semiconductor substrate 102′ underlying the portion of the respective fin structure 100 may be removed to form recesses 100R and a respective etched fin structure 100_1 between two adjacent recesses 100R. The S/D regions will be subsequently formed in the recesses 100R, and the recesses 100R may be referred to as S/D recesses. The recesses 100R may be formed by etching the sidewall spacer layer 205, the underlying fin structures 100, and the underlying semiconductor substrate 102′ using suitable etching processes (e.g., anisotropic etching or the like). The respective recess 100R may extend through the respective fin structure 100 to form the etched fin structure 100_1. In some embodiments, outer sidewalls of the sidewall spacer layer 205 are substantially aligned with sidewalls of the etched fin structure 100_1. In some embodiments, the respective recess 100R extends further into the underlying semiconductor substrate 102′ to form a semiconductor substrate 102. The semiconductor substrate 102 may include bottom fin portions (also called mesa portions, protrusions or base portion) 1021 and recess portions 1022 laterally connected to adjacent two of the bottom fin portions 1021. The respective recess portion 1022 may have a top surface 102t which can be a flat surface, a curved (e.g., concave) surface, or combinations thereof, depending on the etching process. The top surfaces of the bottom fin portions 1021 are higher than the top surfaces 301t of the isolation structures 301

Referring to FIGS. 6-7 and with reference to FIG. 5, portions of the first semiconductor layers 104 exposed by the recesses 100R may be removed in the lateral direction (e.g., the direction D2) to form a respective etched fin structure 100_2 having etched first semiconductor layers 104′. The removal may be performed by using, e.g., isotropic etching processes or other suitable removal techniques. For example, the etchant of the selective etching process is chosen so that the portions of the first semiconductor layers 104 are removed to form lateral recesses, while the second semiconductor layers 106 remain substantially intact during the etching. The respective etched first semiconductor layer 104′ may be laterally recessed from the sidewalls of the underlying (or overlying) second semiconductor layer 106. Although sidewalls of the etched first semiconductor layers 104′ adjacent the lateral recesses 104R are illustrated as being straight in FIG. 6, the sidewalls of the etched first semiconductor layers 104′ may be concave or convex.

With continued reference to FIGS. 6-7, inner sidewall spacers 212 may then be formed in the lateral recesses alongside the etched first semiconductor layers 104′. For example, the inner sidewall spacers 212 are formed along the etched ends of each of the etched first semiconductor layers 104′ and along respective ends of each of the etched first semiconductor layers 104′ and the second semiconductor layers 106. The inner sidewall spacers 212 may be formed of silicon nitride, silicon carbon-nitride, silicon-carbon-oxynitride, combination thereof, or any other type of dielectric material(s), and may be deposited using, e.g., a conformal deposition process and subsequent etching back to remove excess spacer materials on the sidewalls of the etched fin structure 100_2 and on the top surfaces 102t of the semiconductor substrate 102. In some embodiments, the inner sidewall spacers 212 are formed of a material different from the sidewall spacer layer 205. The sidewall spacer layer 205 may serve as an etch mask during the removal of the excess spacer materials, and thus the outer sidewalls of the sidewall spacer layer 205 may be substantially aligned with outer sidewalls of the underlying second semiconductor layers 106 and outer sidewalls of the inner sidewall spacers 212.

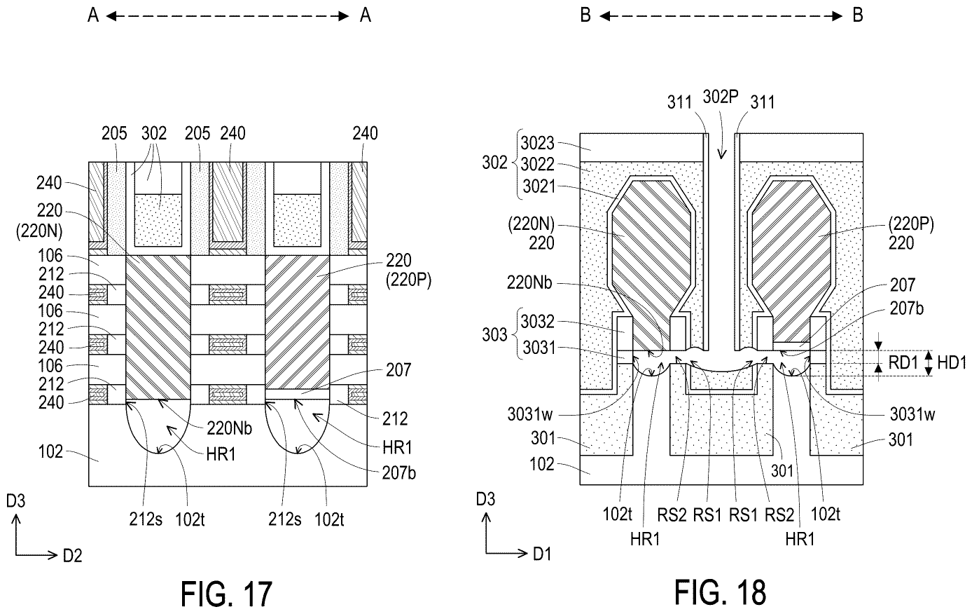

Referring to FIG. 8 and with reference to FIGS. 6-7, sacrificial semiconductor layers 206 may be formed in the recesses 100R and on the top surfaces 102t of the semiconductor substrate 102. The sacrificial semiconductor layers 206 may be considered sacrificial in the sense that they may be ultimately removed (see FIGS. 17-18). In some embodiments, the material of the sacrificial semiconductor layers 206 is different from the material of the semiconductor substrate 102 and the material of the second semiconductor layer 106. The sacrificial semiconductor layers 206 may have the same material (e.g., silicon germanium) as the material of the etched first semiconductor layers 104′. The sacrificial semiconductor layers 206 may include other suitable semiconductor material(s) and may be configured to facilitate subsequent fabrication steps for forming epitaxial structures thereon. In some embodiments, the top surface 206t of the respective sacrificial semiconductor layer 206 is not beyond the bottom surface 106b of the bottommost one of the second semiconductor layers 106. For example, the top surface 206t of the respective sacrificial semiconductor layer 206 is between the top surface 212t and the bottom surface 212b of the bottommost one of the inner sidewall spacers 212. In some embodiments, a semiconductor layer 207 is formed in some of the recesses 100R and on the sacrificial semiconductor layers 206. The sacrificial semiconductor layer 206 may be thicker than the semiconductor layer 207. In some embodiments, the semiconductor layer 207 and the underlying sacrificial semiconductor layer 206 are made of different semiconductor materials. For example, the sacrificial semiconductor layer 206 is made of silicon germanium, while the semiconductor layer 207 overlying the sacrificial semiconductor layer 206 is made of silicon.

Referring to FIG. 9 and with reference to FIG. 8, epitaxial structures 220 may be formed on the sacrificial semiconductor layers 206 and in the recesses 100R. The epitaxial structures 220 may be coupled to the outer sidewalls of the second semiconductor layers 106 and the inner sidewall spacers 212 along the direction D1. The respective epitaxial structure 220 may include a crystalline semiconductor material such as silicon germanium, indium arsenide, indium gallium arsenide, indium antimonide, germanium arsenide, germanium antimonide, indium aluminum phosphide, indium phosphide, any other suitable material, or combinations thereof. The epitaxial structures 220 may be doped with conductive dopants to form S/D regions. It should be noted that S/D region(s) may refer to a source or a drain, individually or collectively dependent upon the context. In addition, the terms “epitaxial structures” and “S/D regions” may be used interchangeably herein. In some embodiments, the epitaxial structures 220 are doped with different types of dopants. As shown in FIG. 9, one of the epitaxial structures 220 (e.g., 220N) is configured for an n-type FET, and the other one of the epitaxial structures 220 (e.g., 220P) is configured for a p-type FET. In some other embodiments, the epitaxial structures 220 are doped with the same type of dopants (e.g., p-type dopants or n-type dopants) and configured for the same type of FET. In some embodiments, the epitaxial structure 220P is grown on the semiconductor layer 207 overlying the sacrificial semiconductor layer 206, while the epitaxial structure 220N is grown on the sacrificial semiconductor layer 206. The epitaxial structures 220 epitaxially grown on the exposed top surfaces 206t of the sacrificial semiconductor layers 206 and the epitaxial structures 220 epitaxially grown on the exposed top surfaces of the semiconductor layers 207 may provide substantially defect-free epitaxial features.

With continued reference to FIG. 9, an interlayer dielectric (ILD) structure 302 may be formed over the epitaxial structures 220. For example, the ILD structure 302 includes an etch stop layer 3021 lining the sidewalls of the sidewall spacer layer 205 and the top surfaces of the epitaxial structures 220, a first dielectric layer 3022 disposed over the epitaxial structures 220 and wrapped around by the etch stop layer 3021, and a second dielectric layer 3023 overlying the first dielectric layer 3022 and laterally covered by the etch stop layer 3021. In some embodiments, the etch stop layer 3021 has a different material then the material(s) of the first dielectric layer 3022 and/or the second dielectric layer 3023. The etch stop layer 3021 may include a dielectric material (e.g., silicon nitride, silicon oxide, silicon oxynitride, or the like). For example, the etch stop layer 3021 may have a different etch rate than the material of the first dielectric layer 3022 and the material of the second dielectric layer 3023. The first dielectric layer 3022 and the second dielectric layer 3023 may be formed of a dielectric material including phosphosilicate glass (PSG), borosilicate glass (BSG), boron-doped phosphosilicate glass (BPSG), undoped silicate glass (USG), or the like. In some embodiments, a planarization process (e.g., chemical mechanical polishing (CMP), grinding, etching back, combinations thereof, or the like) is performed on the ILD structure 302. For example, the mask layer 204 (labeled in FIG. 8) and a portion of the ILD materials laterally adjoining the mask layer 204 are removed after the planarization process. The patterned dummy gate structure 203′ may be accessibly exposed after the planarization process.

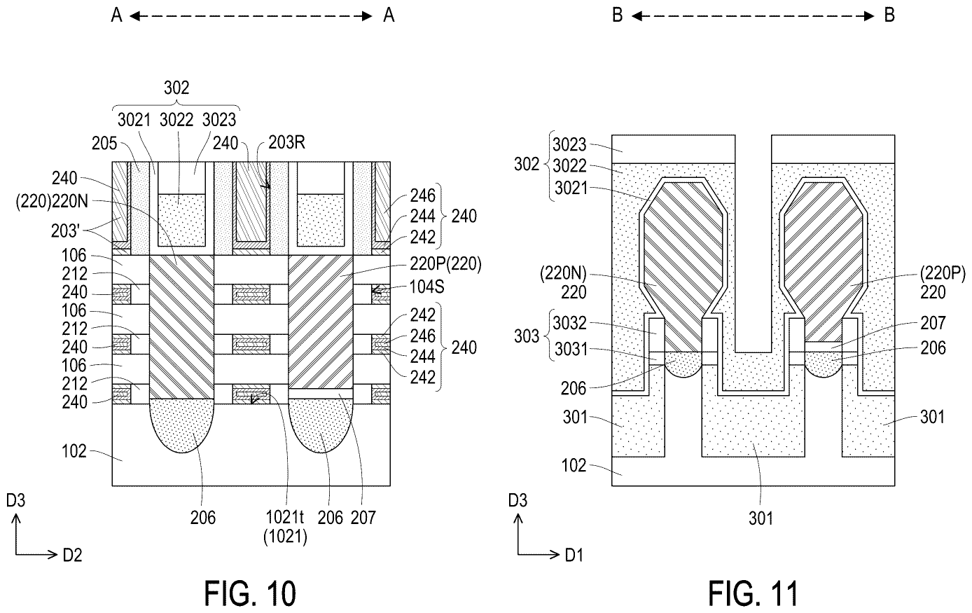

Referring to FIG. 10 and with reference to FIG. 9, a removal process may be performed to remove the patterned dummy gate structure 203′ so as to form a recess 203R. The removal process may include one or more etching steps. For example, the etching step(s) that selectively etch the patterned dummy gate structure 203′ at a faster rate than the ILD structure 302 or the sidewall spacer layer 205. Next, the etched first semiconductor layers 104′ may be removed by etching (e.g., isotropic etching or the like). For example, using etchants which are selective to the materials of the etched first semiconductor layers 104′, while the second semiconductor layers 106, the ILD structure 302, the sidewall spacer layer 205, and the inner sidewall spacers 212 may remain relatively un-etched as compared to the etched first semiconductor layers 104′. During the step of removing the etched first semiconductor layers 104′, the epitaxial structures 220 may be protected by the ILD structure 302. After the removal of the etched first semiconductor layers 104′, respective bottom and top surfaces of each second semiconductor layers 106 and the top surface of the semiconductor substrate 102 may be exposed by recesses 104S.

With continued reference to FIG. 10, a respective gate structure 240 may be formed around the second semiconductor layers 106 and fills the recesses 203R and 104S. The respective gate structure 240 may include a gate dielectric layer 244 and a gate metal layer 246 wrapping around each second semiconductor layer 106 with the gate dielectric layer 244 disposed therebetween, where the second semiconductor layers 106 (also referred to as semiconductor nanosheets or channel layers) function as channel regions. The gate dielectric layer 244 may be a single high-k dielectric material or may include a stack of multiple high-k dielectric materials. Other suitable dielectric material(s) may be used to form the gate dielectric layer 244. The gate metal layer 246 may include a number of sections abutted to each other, each of the gate metal sections may extend not only along a horizontal plane (e.g., the X-Y plane), but also along a vertical direction (e.g., the direction D3). The gate metal layer 246 may include a stack of multiple metal materials. For example, one or more work function sublayers are interposed between the gate dielectric layer 244 and the gate metal layer 246, wherein the work function sublayers may be formed separately for the n-type FET and the p-type FET which may use different metal layers.

With continued reference to FIG. 10, the respective gate structure 240 may include an interfacial layer 242 formed between each second semiconductor layer 106 and the gate dielectric layer 244 and between the semiconductor substrate 102 and the bottommost gate dielectric layer 244. In the cross-sectional view of FIG. 10, the interfacial layer 242 may be formed on the top and bottom surfaces of each second semiconductor layer 106 and on the top surface 1021t of the respective bottom fin portion 1021 of the semiconductor substrate 102, and then the gate dielectric layer 244 is formed on the interfacial layer 242 and also formed on the sidewalls of the inner sidewall spacers 212. The gate metal layer 246 may be formed in the rest space of the respective recess 203R and 104S. In some embodiments, after sequentially depositing the materials of the gate structures 240, excess materials of the gate structures 240 may be removed by a planarizing process, so that the top surface of the topmost gate structure 240 is substantially leveled (e.g., coplanar) with top surfaces of the ILD structure 302 and the sidewall spacer layers 205, within process variations.

Referring to FIG. 11 and with continued reference to FIG. 10, the structure in FIG. 11 is a different cross-sectional view after the formation of the gate structures 240. Note that FIG. 11 is a schematic cross-sectional view taken along the line B-B in FIG. 7, and the gate structures 240 are not shown in the cross-sectional view of FIG. 11. FIG. 11 shows that the respective epitaxial structure 220 is grown on the sacrificial semiconductor layers 206 or the semiconductor layer 207. The epitaxial structures 220 epitaxially grown on the semiconductor materials may advantageously reduce or prevent the defects (e.g., dislocation) formed in the epitaxial structures 220, thereby improving the resulting device performance and yield.

The cross-sectional view of FIG. 11 also shows that the sacrificial semiconductor layer 206 and the combination of the semiconductor layer 207 and the underlying the sacrificial semiconductor layer 206 are laterally covered by the hard mask structure 303. The hard mask structure 303 may be formed prior to or after the formation of the gate structure 240 (i.e., gate replacement process). The hard mask structure 303 may include a first mask layer 3031 overlying the respective isolation structure 301 and a second mask layer 3032 overlying the first mask layer 3031, where the first mask layer 3031 and the second mask layer 3032 may be made of different dielectric materials. In some embodiments, the first mask layer 3031 laterally covers the sacrificial semiconductor layer 206, and the second mask layer 3032 laterally covers the lower portion of the epitaxial structures 220N. The second mask layer 3032 may laterally cover the lower portion of the epitaxial structures 220P and the semiconductor layer 207 interposed between the epitaxial structures 220P and the sacrificial semiconductor layer 206. The upper portions of the epitaxial structure 220P and epitaxial structure 220N may be wrapped around by the etch stop layer 3021 of the ILD structure 302. The etch stop layer 3021 may separate the first dielectric layer 3022 from the hard mask structure 303 and also separate the first dielectric layer 3022 from the isolation structures 301.

Referring to FIG. 12 and with reference to FIG. 7 and FIG. 11, a patterned mask layer 51 may be formed on the respective gate structure 240 and the sidewall spacer layer 205 lining the respective gate structure 240. The ILD structure 302 may be exposed by the patterned mask layer 51. The material of the patterned mask layer 51 may be different from the ILD structure 302 (e.g., the first dielectric layer 3022 and the second dielectric layer 3023). Note that FIG. 12 is a schematic cross-sectional view taken along the line C-C in FIG. 7, and this cross-sectional view may be referred to as the X-cut view on the isolation structures 301. Therefore, the epitaxial structures 220 are not shown in this cross-sectional view. At this stage, the Y-cut view showing the epitaxial structures 220 may be the same as the structure illustrated in the cross-sectional view of FIG. 11.

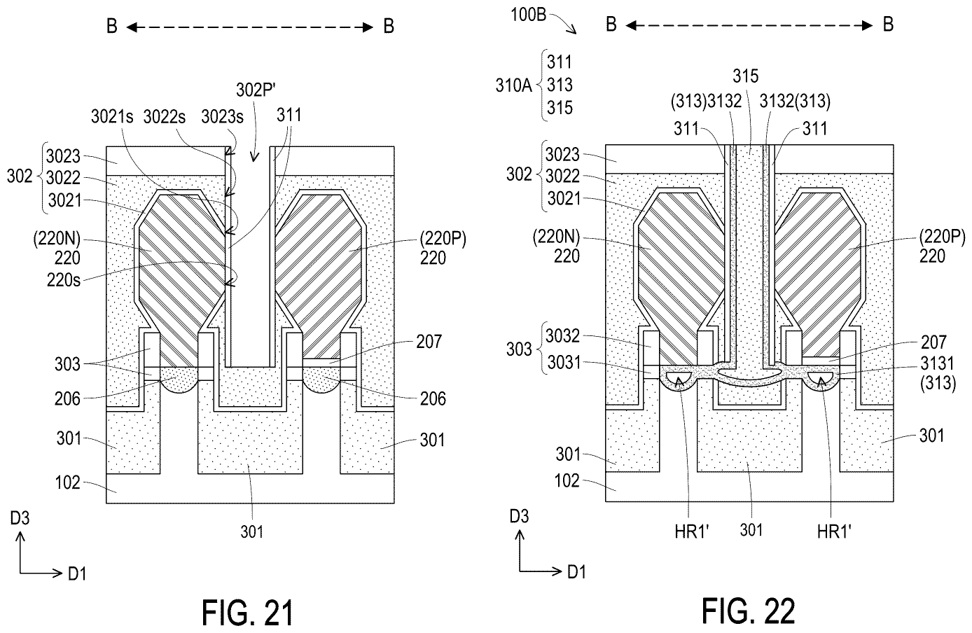

Referring to FIG. 13 and with reference to FIGS. 11-12, after forming the patterned mask layer 51, an opening 302P may be formed in the ILD structure 302 by etching or any suitable removing process. For example, a portion of the second dielectric layer 3023 and a portion of the first dielectric layer 3022 underlying the portion of the second dielectric layer 3023 are removed to form the opening 302P. During the formation of the opening 302P, the gate structure 240 and the sidewall spacer layer 205 may be protected by the patterned mask layer 51. The opening 302P may be formed between adjacent two of the epitaxial structures 220. In the present embodiment, the opening 302P is formed between adjacent two of the epitaxial structures (220N and 220P). In alternative embodiments, the opening 302P is formed between adjacent two of the epitaxial structures 220N or between adjacent two of the epitaxial structures 220P. The opening 302P may not penetrate through the first dielectric layer 3022 and may not expose the etch stop layer 3021. In some embodiments, the bottom surface 3022b of the first dielectric layer 3022 exposed by the opening 302P is substantially coplanar with the top surface 3031t of the first mask layer 3031. In alternative embodiments, the bottom surface 3022b of the first dielectric layer 3022 exposed by the opening 302P is between the top surface 3031t and the bottom surface 3031b of the first mask layer 3031. The lateral dimension PW1 of the opening 302P measured in the direction D1 may be less than a minimum lateral distance LD1 measured in the direction D and between the epitaxial structures (220N and 220P). In alternative embodiments, the lateral dimension of the opening 302P is substantially equal to or greater than the minimum lateral distance between the epitaxial structures, as will be described later in accompanying with FIG. 21.

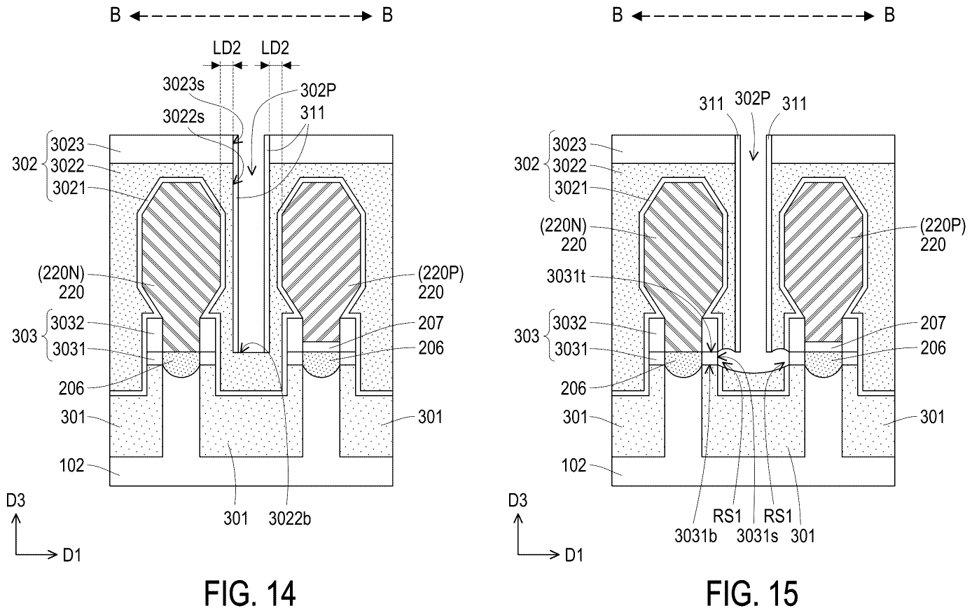

Referring to FIG. 14 and with reference to FIG. 13, a sidewall spacer layer 311 may be formed in the opening 302P and on the inner sidewall 3022s of the first dielectric layer 3022 and the inner sidewall 3023s of the second dielectric layer 3023 which define the opening 302P, where the inner sidewall 3022s of the first dielectric layer 3022 is connected to the bottom surface 3022b. The material of the sidewall spacer layer 311 may include one or more dielectric material(s) and may be different from the materials of the ILD structure 302 (e.g., at least the etch stop layer 3021 and the first dielectric layer 3022). For example, the sidewall spacer layer 311 includes one or more materials of silicon oxide (SiO_{X}), silicon nitride (SiN), silicon carbonnitride (SiCN), silicon oxycarbonnitride (SiOCN), silicon oxycarbide (SiOC), hafnium oxide (HfO₂), aluminum oxide (Al₂O₃), a combination thereof, and/or the like. At least a portion of the bottom surface 3022b of the first dielectric layer 3022 may remain exposed by the opening 302P and the sidewall spacer layer 311 for further processing. In some embodiments, a minimum lateral distance LD2 measured in the direction D1 and between the respective epitaxial structure 220 and the sidewall spacer layer 311 is in a range of about 0 and about 8.0 nanometers. It is realized that the lateral distance provided herein is an example, and may be changed to other suitable values depending on process and product requirements. For example, one or more epitaxial structure(s) 220 may be in lateral and direct contact with the sidewall spacer layer 311 (see FIG. 22). In some embodiments, one or more epitaxial structure(s) 220 is/are laterally spaced apart from the sidewall spacer layer 311 by at least the etch stop layer 3021 (and the first dielectric layer 3022 according to some embodiments).

Referring to FIG. 15 and with reference to FIG. 14, a portion of the first dielectric layer 3022 and a portion of the etch stop layer 3021 connected to the portion of the first dielectric layer 3022 may be removed through the opening 302P through etching or any suitable removing process. The portion of the first dielectric layer 3022 may be below the opening 302P and not covered by the sidewall spacer layer 311. The opening 302P may serve as an etch window. In some embodiments, a chemical etching (e.g., radical etching) process is performed to remove the portions of the first dielectric layer 3022 and the etch stop layer 3021. During the removing process of the portions of the first dielectric layer 3022 and the etch stop layer 3021, the sidewall spacer layer 311 may be used to protect regions of the ILD structure 302 while the etching process forms the lateral recesses RS1 into the portions of the first dielectric layer 3022 and the etch stop layer 3021. For example, the etchant of the selective etching process is chosen so that the portions of the first dielectric layer 3022 and the etch stop layer 3021 are removed to form the lateral recesses RS1, while the sidewall spacer layer 311 may remain substantially intact during the etching. In some embodiments, sidewalls 3031s of a portion of the first mask layer 3031 connected to the top surface 3031t and the bottom surface 3031b are exposed by the lateral recesses RS1.

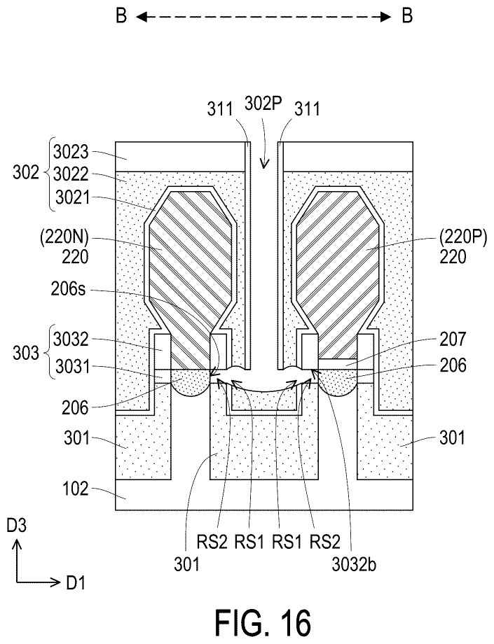

Referring to FIG. 16 and with reference to FIG. 15, the portion of the first mask layer 3031 having the sidewall 3031s exposed by the lateral recesses RS1 may be removed through the opening 302P and the lateral recesses RS1 so as to form the lateral recesses RS2. In some embodiments, an etching process or other suitable removal process is performed to remove the portion of the first mask layer 3031. For example, sidewalls 206s of the sacrificial semiconductor layers 206 and a bottom surface 3032b of the second mask layer 3032 are accessibly exposed by the lateral recesses RS2. In some embodiments, the sidewall spacer layer 311 and the first mask layer 3031 are made of different materials, and the etchant of the selective etching process is chosen so that the portion of the first mask layer 3031 is removed to form the lateral recesses RS2, while the sidewall spacer layer 311 may remain substantially intact during the etching.

Referring to FIGS. 17-18 and with reference to FIG. 10 and FIG. 16, the sacrificial semiconductor layers 206 may then be removed through the opening 302P and the lateral recesses RS2 so as to form hollow regions HR1. In some embodiments, an etching process or other suitable removal process is performed to remove the sacrificial semiconductor layers 206. For example, a bottom surface 220Nb of the epitaxial structure 220N and a bottom surface 207b of the semiconductor layer 207 are exposed by the hollow regions HR1. In some embodiments, the respective sacrificial semiconductor layer 206 has a different material than the sidewall spacer layer 311, the ILD structure 302, the hard mask structure 303, the epitaxial structure 220N, and the semiconductor layer 207. The etchant of the selective etching process may be chosen so that the sacrificial semiconductor layers 206 are removed to form the hollow regions HR1, while the sidewall spacer layer 311, the ILD structure 302, the hard mask structure 303, the epitaxial structure 220N, and the semiconductor layer 207 may remain substantially intact during the etching.

As shown in the cross-sectional view of FIG. 17, the hollow region HR1 underlying the epitaxial structure 220N may be defined by the bottom surface 220Nb of the epitaxial structure 220N, the sidewalls 212s of the bottommost one of the inner spacers 212, and the top surfaces 102t of the semiconductor substrate 102. The hollow region HR1 below the epitaxial structure 220P may be defined by the bottom surface 207b of the semiconductor layer 207, the sidewalls 212s of the bottommost one of the inner spacers 212, and the top surfaces 102t of the semiconductor substrate 102. As shown in the cross-sectional view of FIG. 18, the hollow region HR1 underlying the epitaxial structure 220N may be defined by the bottom surface 220Nb of the epitaxial structure 220N, the sidewall 3031w of the first mask layer 3031, and the top surface 102t of the semiconductor substrate 102. The hollow region HR1 below the epitaxial structure 220P may be defined by the bottom surface 207b of the semiconductor layer 207, the sidewalls 3031w of the first mask layer 3031, and the top surface 102t of the semiconductor substrate 102. As shown in the cross-sectional view of FIG. 18, the hollow regions HR1 underlying the epitaxial structures (220N and 220P) may be in communication with the lateral recesses RS2. For example, the maximum depth HD1 of the respective hollow region HR1 is greater than the maximum depth RD1 of the respective lateral recess RS2.

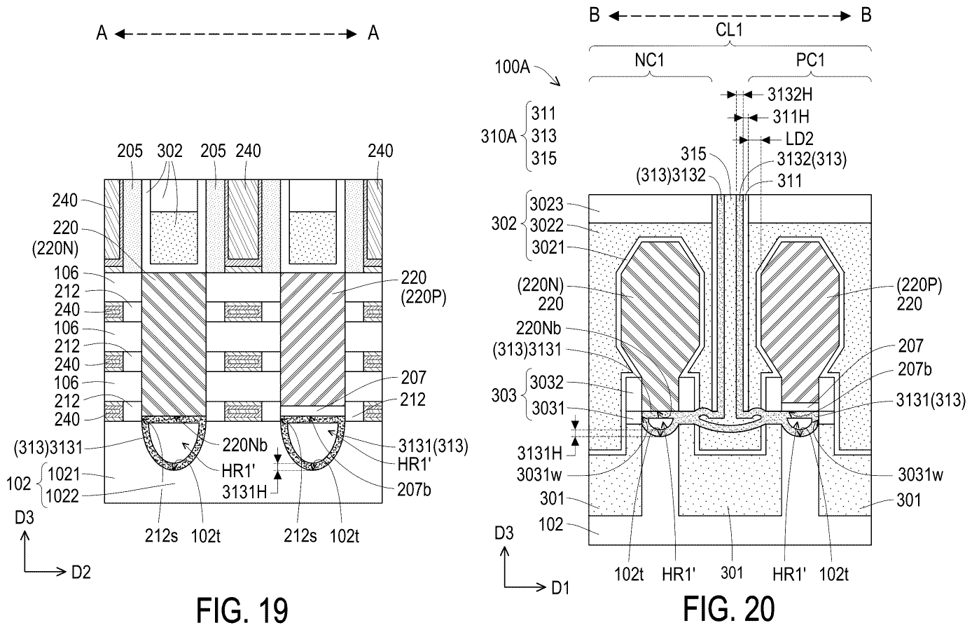

Referring to FIGS. 19-20 and with reference to FIGS. 17-18, a liner layer 313 may be formed on the sidewall spacer layer 311 and extends to line the lateral recesses (RS1 and RS2) and the hollow regions HR1. The material(s) of the liner layer 313 may include SiO_{X}, SiN, SiCN, SiOCN, SiOC, silicon oxynitride (SiON), the like, a combination thereof, etc. In some embodiments, the liner layer 313 has a material different from the sidewall spacer layer 311. The liner layer 313 may be formed by ALD or other suitable deposition process (e.g., CVD, PVD, or the like). When forming the liner layer 313, e.g., by ALD, the liner material may be deposited layer-by-layer with conformal coating the structures through the opening 302P, the lateral recesses (RS1 and RS2), and the hollow regions HR1. The lateral recesses RS2 may then be filled with the liner material. As mentioned in FIG. 18, since the maximum depth RD1 of the respective lateral recess RS2 is less than the maximum depth HD1 of the respective hollow region HR1, the hollow region HR1 may not be entirely filled with the liner material as the lateral recesses RS2 are sealed with the liner material. Thus, a gap (e.g., an air gap) may remain in the hollow regions HR so as to form the hollow regions HR1′ encircled by a first portion 3131 of the liner layer 313. For example, the depth and/or the width of the hollow regions HR1′ may be non-zero.

As shown in the cross-sectional view of FIG. 19, the first portion 3131 of the liner layer 313 encircling the hollow region HR1′ underlying the epitaxial structure 220N may cover or be in contact with the bottom surface 220Nb of the epitaxial structure 220N, the sidewalls 212s of the bottommost one of the inner spacers 212, and the top surfaces 102t of the recess portions 1022 of the semiconductor substrate 102. The first portion 3131 of the liner layer 313 encircling the hollow region HR1′ below the epitaxial structure 220P may cover or be in contact with the bottom surface 207b of the semiconductor layer 207, the sidewalls 212s of the bottommost one of the inner spacers 212, and the top surfaces 102t of the semiconductor substrate 102.

As shown in the cross-sectional view of FIG. 20, the first portion 3131 of the liner layer 313 encircling the hollow region HR1′ underlying the epitaxial structure 220N may cover or be in contact with the bottom surface 220Nb of the epitaxial structure 220N, the sidewall 3031w of the first mask layer 3031, and the top surface 102t of the semiconductor substrate 102. The first portion 3131 of the liner layer 313 encircling the hollow region HR1′ below the epitaxial structure 220P may cover or be in contact with the bottom surface 207b of the semiconductor layer 207, the sidewalls 3031w of the first mask layer 3031, and the top surface 102t of the semiconductor substrate 102. As shown in the cross-sectional views of FIGS. 19-20, a maximum thickness 3131H of the first portion 3131 of the liner layer 313 encircling the respective hollow region HR1′ is non-zero. For example, the maximum thickness 3131H is in a range of about 0.5 nanometers and about 4.0 nanometers.

As shown in the cross-sectional view of FIG. 20, a second portion 3132 of the liner layer 313 lining the sidewall spacer layer 311 may include a maximum thickness 3132H ranging from about 0.5 nanometers to about 4.0 nanometers. In some embodiments, the maximum thickness 3132H of the second portion 3132 measured along the direction D1 is substantially equal to or greater than the maximum thickness 313H of the first portion 3131 measured in the direction D3. In some embodiments, a maximum thickness 311H of the sidewall spacer layer 311 on the sidewalls of the ILD structure 302 is in a range of about 0.5 nanometers and about 3.0 nanometers. It is realized that the thicknesses provided herein are examples, and may be changed to other suitable values depending on process and product requirements.

With continued reference to FIG. 20, a gap-fill layer 315 may be formed on the liner layer 313. For example, the rest space of the opening 302P and the lateral recess RS1 is filled with a gap-fill layer 315 through any suitable deposition process (e.g., CVD, PVD, ALD, or the like). The gap-fill layer 315 may include one or more dielectric material(s) such as SiO_{X}, SiN, SiOCN, SiOC, the like, a combination thereof, etc. The gap-fill layer 315 may be made of the same material as the liner layer 313. Alternatively, the gap-fill layer 315 and the liner layer 313 are made of different materials. The cross-sectional view of the semiconductor device 100A shown in FIG. 20 shows a cell CL1 including a region NC1 and a region PC1 laterally spaced apart from the region NC1, where the region NC1 may include the epitaxial structure 220N configured for an n-type FET and the region PC1 may include the epitaxial structure 220P configured for a p-type FET. The semiconductor device 100A may include an isolation structure 310A laterally interposed between the region NC1 and the region PC1, where the isolation structure 310A includes the sidewall spacer layer 311, the liner layer 313, and the gap-fill layer 315. The isolation structure 310A disposed in the cell CL1 may be referred to as the in-cell isolation.

By epitaxially growing the epitaxial structure 220N on the sacrificial semiconductor layer 206 and epitaxially growing the epitaxial structure 220P on the semiconductor layer 207, the epitaxial structures (220N and 220P) may have defect-free structures or reduced defects. The parasitic resistance of the semiconductor device 100A may be reduced. After the formation of the epitaxial structures (220N and 220P), the sacrificial semiconductor layers 206 below the epitaxial structures (220N and 220P) are removed to form the hollow regions HR1. The liner layer 313 may then be formed in the hollow regions HR1 to serve as isolation between the respective epitaxial structure (220N or 220P) and the respective bottom fin portion 1021 of the semiconductor substrate 102, thereby reducing the parasitic capacitance and leakage current. Therefore, the performance of the semiconductor device 100A may be improved.

FIGS. 21-22 illustrate schematic cross-sectional views of intermediate steps during a process for forming a semiconductor device 100B, in accordance with some embodiments. Unless specified otherwise, the components in FIGS. 21-22 are essentially the same as the like components denoted by like reference numerals in FIGS. 14 and 20. Referring to FIG. 21 and with reference to FIG. 14, the structure shown in FIG. 21 is similar to the structure shown in FIG. 14, and thus the detailed descriptions are not repeated for the sake of brevity. The difference therebetween includes that a portion of the etch stop layer 3021 lining the respective epitaxial structure 220 may be removed after forming the opening 302P', and the sidewall spacer layer 311 may be formed on the exposed surface of the respective epitaxial structure 220. For example, the lateral dimension of the epitaxial structures 220 in FIG. 21 is greater than that of the epitaxial structures 220 in FIG. 14. The adjacent two of the epitaxial structures 220 in FIG. 21 may have a narrower spacing, and thus after the formation of the opening 302P', a portion of the etch stop layer 3021 lining the respective epitaxial structure 220 may be removed to expose the surfaces of the epitaxial structures 220. The sidewall spacer layer 311 may then be formed on the inner sidewall 3022s of the first dielectric layer 3022, the inner sidewall 3023s of the second dielectric layer 3023, the etched surface 220s of the respective epitaxial structure 220, and the etched surfaces 3021s of the etch stop layer 3021 connected to the etched surface 220s.

Referring to FIG. 22 and with reference to FIG. 21 and FIG. 20, the subsequent processes after the formation of the sidewall spacer layer 311 may be similar to the processes described in FIGS. 15-20, and thus the detailed descriptions are not repeated for the sake of brevity. The difference between the semiconductor device 100B and the semiconductor device 100A shown in FIG. 20 may include that the sidewall spacer layer 311 of the isolation structure 310A is in lateral and physical contact with the respective epitaxial structure 220.

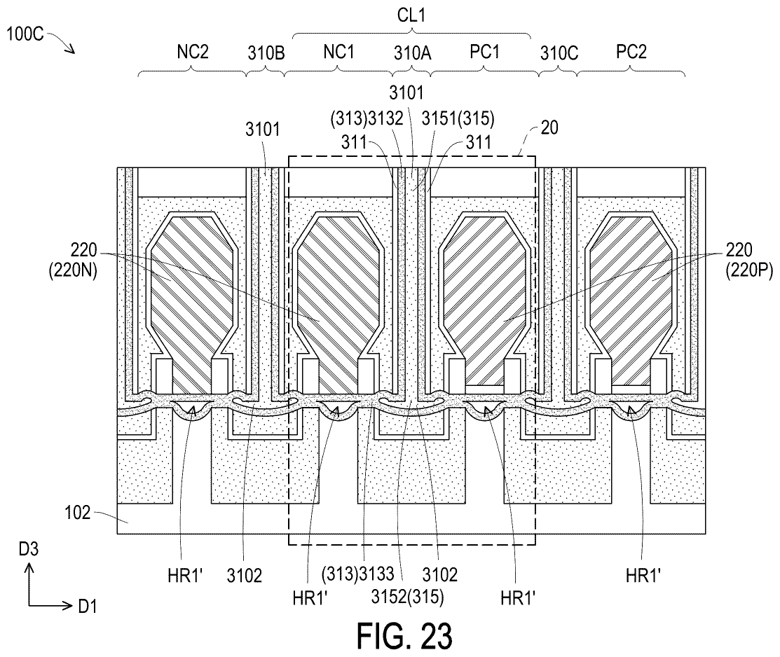

FIGS. 23-25 illustrates schematic cross-sectional views of variations of a semiconductor device, in accordance with some embodiments. Unless specified otherwise, the components in FIGS. 23-25 are essentially the same as the like components denoted by like reference numerals in FIG. 20. Referring to FIG. 23 and with reference to FIG. 20, the semiconductor device 100C includes a plurality of regions (e.g., NC1, NC2, PC1, and PC2), where the regions (NC1 and NC2) may each include the epitaxial structure 220N configured for an n-type FET, and the regions (PC1 and PC2) may each include the epitaxial structure 220P configured for a p-type FET. The region PC1 may be laterally interposed between the region NC1 and the region PC2, and the region NC1 may be laterally interposed between the region NC2 and the region PC1. The regions (NC1 and PC1) may form the cell CL1 of the semiconductor device 100C, and the portion of the semiconductor device 100C outlined in the dashed box 20 and including the regions (NC1 and PC1) is the same as the structure shown in FIG. 20, and thus the detailed descriptions are omitted for the sake of brevity.

In some embodiments, the semiconductor device 100C includes a plurality of isolation structure (e.g., 310A-310C) configured for isolating the epitaxial structure 220 of each region from the semiconductor substrate 102. For example, the isolation structure 310A serving as in-cell isolation has a first portion 3101 extending along the direction D3 and a second portion 3102 connected to the first portion 3101 and extending along the direction D1. The first portion 3101 of the isolation structure 310A may be laterally interposed between the epitaxial structures (220N and 220P) and include the sidewall spacer layer 311, the second portion 3132 of the liner layer 313 lining the sidewall spacer layer 311, and the upper portion 3151 of the gap-fill layer 315 laterally covered by the second portion 3132 of the liner layer 313. The second portion 3102 of the isolation structure 310A may include the first portion 3131 of the liner layer 313 encircling the hollow region HR1', the lower portion 3152 of the gap-fill layer 315 connected to the upper portion 3151, and the third portion of the liner layer 313 connected to the first portion 3131 and the second portion 3132 and lining the lower portion 3152 of the gap-fill layer 315.

With continued reference to FIG. 23, the isolation structure 310B disposed between the regions (NC1 and NC2) and the isolation structure 310C disposed between the regions (PC1 and PC2) may be viewed as the cell-boundary isolations. The isolation structure 310B, similar to the isolation structure 310A, may include the first portion 3101 laterally interposed between the epitaxial structures 220N and the second portion 3102 connected to the first portion 3101. The isolation structure 310C, similar to the isolation structure 310A, may include the first portion 3101 laterally interposed between the epitaxial structures 220P and the second portion 3102 connected to the first portion 3101.

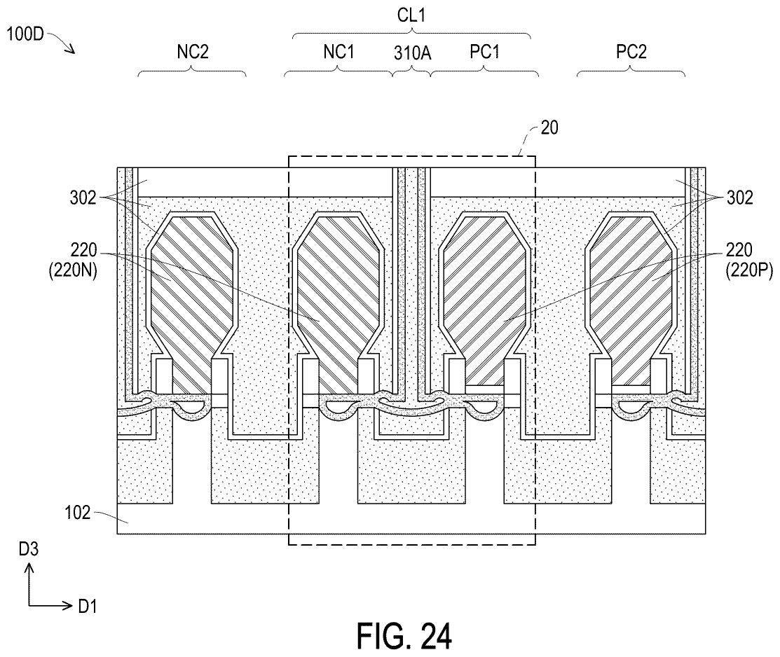

Referring to FIG. 24 and with reference to FIG. 23, the semiconductor device 100D may be similar to the semiconductor device 100C, except that the cell-boundary isolations (e.g., the isolation structures 310B and 310C) are omitted. The semiconductor device 100D may include the in-cell isolation (e.g., the isolation structure 310A) interposed between the regions (NC1 and PC1). The ILD structure 302 covering the epitaxial structure 220N in the region NC1 may continuously extend to cover the epitaxial structure 220N in the region NC2, and no cell-boundary isolation is disposed between the regions (NC1 and NC2). Similarly, the ILD structure 302 covering the epitaxial structure 220P in the region PC1 may continuously extend to cover the epitaxial structure 220P in the region PC2, and no cell-boundary isolation is disposed between the regions (PC1 and PC2).

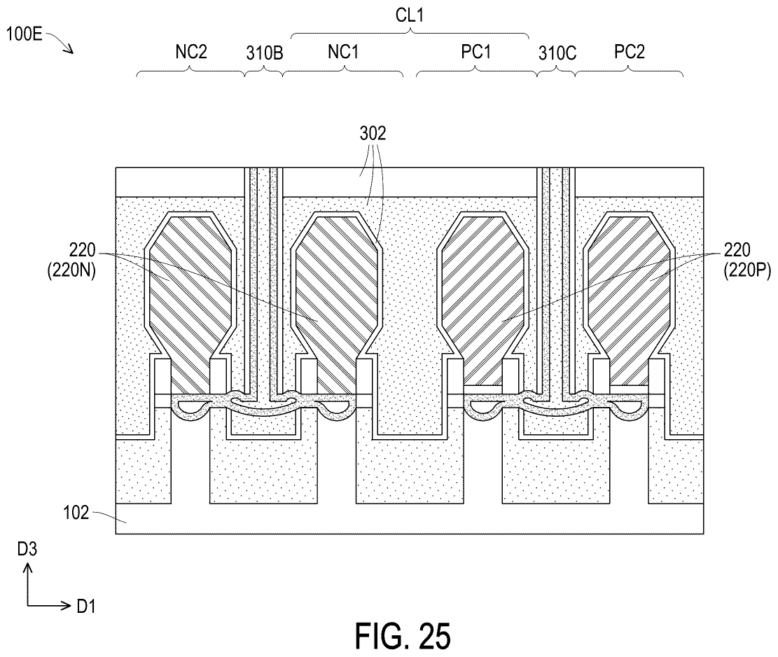

Referring to FIG. 25 and with reference to FIG. 23, the semiconductor device 100E may be similar to the semiconductor device 100C, except that the in-cell isolation (e.g., the isolation structure 310A) between the regions (NC1 and PC1) of the cell CL1 is omitted. For example, the ILD structure 302 covering the epitaxial structure 220N in the region NC1 may continuously extend to cover the epitaxial structure 220P in the region PC1, and no in-cell isolation is disposed between the regions (NC1 and PC1). The semiconductor device 100E may include the cell-boundary isolation (e.g., the isolation structures 310B and 310C) surrounding the cell CL1.

By epitaxially growing the epitaxial structures on the sacrificial semiconductor layer or on the semiconductor layer, the defects on the epitaxial structures may be reduced or eliminated. The parasitic resistance of the resulting semiconductor device may thus be reduced. After the formation of the epitaxial structures, the sacrificial semiconductor layers below may be removed to form the hollow regions. The liner layer of the isolation structure may then be formed in the hollow regions to isolate the epitaxial structures from the semiconductor substrate (e.g., the mesa), thereby reducing the parasitic capacitance and leakage current. Therefore, both of the parasitic resistance and the parasitic capacitance may be reduced, and thus the performance of the resulting semiconductor device may be improved.

According to some embodiments, a semiconductor device includes semiconductor device includes a semiconductor substrate, semiconductor channel layers disposed over the semiconductor substrate and vertically spaced apart from one another, a gate structure disposed between adjacent two of the semiconductor channel layers and between the semiconductor substrate and a bottommost one of the semiconductor channel layers, source/drain (S/D) structures disposed over the semiconductor substrate and laterally connecting the semiconductor channel layers, and a liner layer including a first portion disposed below the S/D structures to isolate each of the S/D structures from the semiconductor substrate. The gate structure is disposed between the S/D structures, and hollow regions below the S/D structures are encircled by the first portion of the liner layer.

According to some alternative embodiments, a semiconductor device includes a semiconductor substrate including protrusions and a portion between the protrusions, semiconductor channel layers vertically disposed over the bottom fin portion, a gate structure disposed around the semiconductor channel layers, S/D structures disposed over the portion and laterally abutting the semiconductor channel layers, and a liner layer including a first portion lining the S/D structures and the portion. A hollow region is encircled by the first portion of the liner layer.

According to some alternative embodiments, a method of forming a semiconductor device includes forming semiconductor channel layers over a semiconductor substrate, where the semiconductor substrate includes a bottom fin portion and a recess portion, and the semiconductor channel layers formed over the bottom fin portion; forming a semiconductor sacrificial layer on the recess portion of the semiconductor substrate; growing an epitaxial structure on semiconductor sacrificial layer, wherein the epitaxial structure is laterally abutted the semiconductor channel layers; forming a gate structure between adjacent two of the semiconductor channel layers and between the bottom fin portion of the semiconductor substrate and a bottommost one of the semiconductor channel layers; removing the semiconductor sacrificial layer to form a space between the recess portion of the semiconductor substrate and the epitaxial structure; and forming a first portion of a liner layer in the space to line the recess portion of the semiconductor substrate and the epitaxial structure, where a hollow region is encircled by the first portion of the liner layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor substrate;
semiconductor channel layers disposed over the semiconductor substrate and vertically spaced apart from one another; and
a gate structure disposed between adjacent two of the semiconductor channel layers and between the semiconductor substrate and a bottommost one of the semiconductor channel layers;
source/drain (S/D) structures disposed over the semiconductor substrate and laterally connecting the semiconductor channel layers, the gate structure being disposed between the S/D structures; and
a liner layer comprising a first portion disposed below the S/D structures to isolate each of the S/D structures from the semiconductor substrate, wherein hollow regions below the S/D structures are encircled by the first portion of the liner layer.

2. The semiconductor device of claim 1, further comprising:
an inner spacer comprising a side connected to the gate structure and an opposing side connected to the first portion of the liner layer and the S/D structures.

3. The semiconductor device of claim 1, wherein one of the S/D structures configured for an n-type field effect transistor (FET) is in contact with the first portion of the liner layer.

4. The semiconductor device of claim 1, further comprising:
a semiconductor layer vertically interposed between the first portion of the liner layer and one of the S/D structures, wherein the one of the S/D structures is configured for a p-type field effect transistor (FET).

5. The semiconductor device of claim 1, wherein the liner layer further comprises a second portion extending in a thickness direction of the semiconductor substrate and laterally interposed between adjacent two of the S/D structures.

6. The semiconductor device of claim 5, further comprising:
a sidewall spacer layer laterally interposed between the S/D structures and the second portion of the liner layer, the second portion of the liner layer lining the sidewall spacer layer, and the sidewall spacer layer comprising a different material than the liner layer.

7. The semiconductor device of claim 6, wherein the sidewall spacer layer is in lateral contact with the S/D structures.

8. The semiconductor device of claim 6, further comprising:
a gap-filling layer laterally interposed between the S/D structures, wherein the second portion of the liner layer is laterally between the sidewall spacer layer and the gap-filling layer.

9. The semiconductor device of claim 1, further comprising:
an isolation structure disposed in a recess of the semiconductor substrate, wherein the liner layer comprises a third portion connected to the first portion and disposed on the isolation structure.

10. The semiconductor device of claim 9, wherein the third portion of the liner layer comprises a segment in contact with the isolation structure, and a thickness of the segment is greater than a thickness of the first portion of the liner layer.

11. A semiconductor device, comprising:
a semiconductor substrate comprising protrusions and a portion between the protrusions;
semiconductor channel layers vertically disposed over the protrusions;
a gate structure disposed around the semiconductor channel layers;
S/D structures disposed over the portion and laterally abutting the semiconductor channel layers; and
a liner layer comprising a first portion lining the S/D structures and the portion, wherein a hollow region is encircled by the first portion of the liner layer.

12. The semiconductor device of claim 11, wherein the portion of the semiconductor substrate comprises a concave curved surface lined with the first portion of the liner layer.

13. The semiconductor device of claim 11, further comprising:
an inner spacer laterally separating the gate structure from the S/D structures, wherein the first portion of the liner layer is in lateral contact with the inner spacer.

14. The semiconductor device of claim 11, wherein the liner layer comprises:
a second portion extending in an extending direction of the protrusions and disposed over the portion, the second portion being laterally interposed between adjacent two of the S/D structures.

15. The semiconductor device of claim 14, wherein one of the adjacent two of the S/D structures is doped with an n-type of dopants and the other one of the adjacent two of the S/D structures is doped with a p-type of dopants.

16. The semiconductor device of claim 14, wherein the adjacent two of the S/D structures are doped with a same type of dopants.

17. A manufacturing method of a semiconductor device, comprising:
forming semiconductor channel layers over a semiconductor substrate, wherein the semiconductor substrate comprises a bottom fin portion and a recess portion, and the semiconductor channel layers formed over the bottom fin portion;
forming a semiconductor sacrificial layer on the recess portion of the semiconductor substrate;
growing an epitaxial structure on semiconductor sacrificial layer, wherein the epitaxial structure is laterally abutted the semiconductor channel layers;
forming a gate structure between adjacent two of the semiconductor channel layers and between the bottom fin portion of the semiconductor substrate and a bottommost one of the semiconductor channel layers;
removing the semiconductor sacrificial layer to form a space between the recess portion of the semiconductor substrate and the epitaxial structure; and
forming a first portion of a liner layer in the space to line the recess portion of the semiconductor substrate and the epitaxial structure, wherein a hollow region is encircled by the first portion of the liner layer.

18. The manufacturing method of claim 17, further comprising:
forming an interlayer dielectric (ILD) structure on the epitaxial structure before forming the gate structure; and
forming an opening in the ILD structure after forming the gate structure, wherein the opening is laterally aside the epitaxial structure.

19. The manufacturing method of claim 18, further comprising:
forming a lateral recess at a bottom of the opening to expose the semiconductor sacrificial layer, wherein the semiconductor sacrificial layer is removed through the opening and the lateral recess.

20. The manufacturing method of claim 17, wherein the epitaxial structure is configured for an n-type field effect transistor (FET), and forming the first portion of the liner layer comprises:
lining a bottom surface of the epitaxial structure with the first portion of the liner layer.
